(19) United States
(12) Patent Application Publication
(10) Pub. No.: US 2004/0193979 A1
(43) Pub. Date: Sep. 30, 2004

(54) Circuit configurator arrangement and approach therefor

(75) Inventors: Daniel Lee Avery, Chandler, AZ (US); Joel Patrick Bailey, Chandler, AZ (US); Randall Pendley, Tempe, AZ (US); Allyn Farmer, Scottsdale, AZ (US)

Correspondence Address: Philips Electronics North America Corporation, Intellectual Property & Standards, 1000 W. Maude Ave., Sunnyvale, CA, 94085, US

(73) Assignee: Koninklijke Philips Electronics N.V.

(21) Appl. No.: 10/796,480

(22) Filed: Mar. 8, 2004

Related U.S. Application Data
(60) Provisional application No. 60/459,327, filed on Mar. 31, 2003.

(51) Int. Cl. G01R 31/28

(52) U.S. Cl. 714/724

(57) ABSTRACT

A circuit testing approach involves configurable switch control for automatically detecting and routing test signals along a plurality of test circuit paths. According to an example embodiment of the present invention, a configurator arrangement (100) controls a configured circuit (110) by monitoring test signals and, in response, setting switches (115) on the configured circuit. In one implementation, the configurator circuit arrangement is programmed to automatically detect test signals (i.e., digital and/or JTAG test signals) and to control switches (115) for routing test data along a test circuit path on the configured circuit and/or between the configured circuit and an external circuit. With this approach, manual switching for routing the test signals is not necessary, which has been found to be useful in applications where access to the circuit paths for switching is difficult or impossible. In another implementation, a communications link (130) passes signals between the configurator circuit arrangement (100) and a user interface (140), including control signals from the user interface and data from the configured circuit (110). The configurator circuit arrangement (100) is further controllable (i.e., manually) or programmable by signals received from the user interface (140).

### FIELD OF THE INVENTION

The present invention relates generally to testing electrical circuits and, more particularly, to circuit test methods and arrangements such as used in connection with IEEE JTAG (Joint Test Access Group) standards.

### BACKGROUND

The electronics industry continues to rely upon advances in semiconductor technology to realize higher-functioning devices in more compact areas. For many applications, realizing higher-functioning devices requires integrating a large number of electronic devices into a single silicon wafer. As the number of electronic devices per given area of the silicon wafer increases, manufacturing and testing processes become more difficult.

A wide variety of techniques have been used in electronic circuit devices to ensure that, once they are manufactured, they operate fully in compliance with their intended design and implementation specifications. Many of the more complex circuit designs include circuits that permit in-circuit testing via access pins. The IEEE 1149.1 JTAG recommendation, for example, provides test circuit architecture for use inside such circuits. This architecture includes a test access port (TAP) controller coupled to the pins for providing access to and for controlling various standard features designed into such circuits. Some of these features are internal scan, boundary scan, built-in test and emulation.

For a variety of implementations, different circuit paths are tested using the JTAG recommendation, depending upon the type of test being performed. Mechanical connections (i.e., jumpers) have typically been used to select such a desired circuit path for JTAG-type testing. Setting mechanical connections, however, typically requires access to the connections being set. For example, circuit modules (e.g., permanent and/or reusable blocks, circuit tiles and integrated circuits) can be stacked on top of one another, such that in setting jumpers the circuit modules must be pulled apart. If mistakes are made in setting the jumpers, the process of pulling apart the modules and setting the jumpers must be repeated. The implementation of this mechanical connection-setting approach has been challenging. For example, taking apart modules for making connections involves a risk of damaging the connectors, boards and/or other circuitry involved therewith.

Current JTAG and other circuit testing approaches have typically been limited to the testing of powered circuits. For instance, typical diagnostic testing involves the passage of test signals after power-up of the circuit being tested, with the test signals passing through circuits during the operation thereof. Therefore, JTAG and other circuit testing approaches typically have not been used for testing circuits prior to power-up.

In addition, for many chip designs, customized chips are made by describing their functionality using a hardware-description language (HDL), such as Verilog or VHDL. The hardware description is often written to characterize the design in terms of a set of functional macros. The design is computer simulated to ensure that the custom design criteria are satisfied. For highly-complex custom chip designs, the above process can be burdensome and costly. The highly integrated structure of such chips leads to unexpected problems, such as signal timing, noise-coupling and signal-level issues. Consequently, such complex custom chip designs involve extensive validation. This validation is generally performed at different stages using a Verilog or VHDL simulator. Once validated at this level, the Verilog or VHDL HDL code is synthesized, for example, using “Synopsis,” to a netlist that is supplied to an ASIC (Application Specific Integrated Circuit) foundry for prototype fabrication. The ASIC prototype is then tested in silicon. Even after such validation with the Verilog or VHDL simulator, unexpected problems are typical. Overcoming these problems involves more iterations of the above process, with testing and validation at both the simulation and prototype stages. Such repetition significantly increases the design time and cost to such a degree that this practice is often intolerable in today's time-sensitive market.

These and other difficulties present challenges to the design and testing for a variety of applications.

### SUMMARY

Various aspects of the present invention involve testing approaches for a variety of circuits, such as those including memory circuits and others. The present invention is exemplified in a number of implementations and applications, some of which are summarized below.

According to one example embodiment of the present invention, a programmable configurator arrangement is programmed to route test signals via a selected circuit path on configurable circuit using automatically set switches. In one implementation, the switches are set in response to test signals being detected at an input node of the configurable circuit. With this approach, switching for test data routing is automatically effected, without necessarily involving manual switching approaches, such as those involving the use of jumpers.

In a more particular example embodiment of the present invention, the configurator discussed in the preceding paragraph includes a microcontroller programmed using stored computer-executable code and/or information received from a user interface by way of a communications link. In one implementation, the computer-executable code is sent from the user interface to program memory coupled to the microcontroller (i.e., by way of a bus), with updates to the computer-executable code being made with the user interface.

In another example embodiment, the microcontroller is further configured to monitor characteristics of the configurable circuit and to send information regarding the monitored characteristics to the user interface by way of the communications link. Characteristics that are monitored include, for example, switch settings, clock frequencies, connectivity (e.g., between the configurable circuit and other configurable circuits), board voltages, JTAG operations and diagnostic characteristics. In one implementation, the microcontroller is controlled by the user interface for detecting characteristics of the configurable circuit prior to power-up thereof, which is useful, for instance, in performing diagnostics and/or setting test-signal routing switches before operating the configurable circuit.

The microcontroller is programmed to automatically monitor test data inputs (TDIs) on the configurable circuit for testing signals, in another example embodiment. Upon the detection of a test signal (e.g., a JTAG test signal), the programmed microcontroller identifies a particular circuit path to which the test data is to be routed, and controls switches for routing the test signal between the TDIs and the circuit path. In a more particular implementation, the microcontroller is further programmed to control a switch for routing a response to the test signal to a test data output (TDO). In another more particular implementation, the microcontroller is further controllable using the user interface to control the switches (e.g., to override the programming and manually control the switches).

In another example embodiment of the present invention, an inter-connectable circuit board includes a plurality of circuit paths and controllable switches adapted for routing test data between at least one of the circuit paths and a communications node. A circuit arrangement including program memory and a microcontroller on the inter-connectable circuit board is programmed for controlling the controllable switches using stored programming information in the memory. In response to detecting a test signal at the communications node, computer-executable code in the program memory controls the microcontroller to identify a particular one of the circuit paths to which the test signal is to be routed. The microcontroller then controls the controllable switches to couple a signal path between the communications node and the circuit path. With this approach, access to the inter-connectable circuit board, for example, for connecting jumper lines for switching circuits, is not necessary. This approach has also been found useful when the inter-connectable circuit board is connected to another arrangement such that physical access to the inter-connectable circuit board is difficult or not possible.

The above summary of the present invention is not intended to describe each embodiment or every implementation of the present invention. The above summary of the present invention is not intended to describe each illustrated embodiment or every implementation of the present invention. The figures and detailed description that follow more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 shows a hardware configurator adapted for controlling switch operation for signal passing on an integrated circuit, according to an example embodiment of the present invention;

FIG. 2 is a flow diagram for a power-up step of a hardware configuration approach, according to another example embodiment of the present invention;

FIG. 3 is a flow diagram for a self-test step of a hardware configuration approach, according to another example embodiment of the present invention;

FIG. 4 is a flow diagram for a communications step of a hardware configuration approach, according to another example embodiment of the present invention;

FIG. 5 is a flow diagram for a JTAG interactive configuration detection step of a hardware configuration approach, according to another example embodiment of the present invention;

FIG. 6 is a flow diagram for a JTAG signal detection step of a hardware configuration approach, according to another example embodiment of the present invention;

FIG. 7 is a flow diagram for a controlling switches and interrupt-detect signals for a configuration step of a hardware configuration approach, according to another example embodiment of the present invention; and

FIG. 8 is a circuit arrangement including a programmable circuit configurator programmed for automatically routing test signals, according to another example embodiment of the present invention.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the scope of the invention as defined by the appended claims.

### DETAILED DESCRIPTION

The present invention is believed to be applicable to a variety of circuits and approaches involving and/or benefiting from testing, and in particular to testing involving approaches such as JTAG and digital signal testing (i.e., using digital signal protocols) and the configuration thereof. While the present invention is not necessarily limited to such applications, an appreciation of various aspects of the invention is best gained through a discussion of examples in such an environment.

According to an example embodiment of the present invention, a configurator arrangement is coupled to a configurable circuit and programmed to switch circuit paths in the configurable circuit for passing test signals. A communications link communicates control signals between a user interface and the configurator arrangement. The configurator arrangement controls test signal path switching circuits of the configurable circuit using the control signals and/or programming information stored at the configurator arrangement. In one implementation, the test signal path switching circuits are manually switched in response to control signals from user interface. In another implementation, the configurator arrangement monitors signals in the configurable circuit and automatically switches the test signal path switching circuits. Test signals are then delivered to and/or from a specific circuit that is on the configurable circuit and/or coupled to the configurable circuit (e.g., on a separate circuit board). With these approaches, physical routing (i.e., the switching of jumper wires) is not necessary for delivering test signals to different circuits, and switches on the configurable circuit are remotely controllable with a user interface.

In another example embodiment of the present invention, the configurator arrangement discussed in the preceding paragraph includes a microcontroller that is part of a reusable inter-connectable testing circuit including one or more devices, such as I/O, memory, DSP, power supply and RISC CPU devices. The inter-connectable testing circuit is also adapted for coupling to other circuits, for example, for arranging prototype circuit designs and architectures for testing purposes. When testing such a prototype arrangement, testing signals need to be coupled to various elements, circuit paths and/or other inter-connectable testing circuits. In this regard, the microcontroller is adapted for controlling switches on a particular inter-connectable testing circuit for routing test signals thereon. With this approach, the routing of the test signals is automatic, which has also been found useful in implementations where the inter-connectable circuits are coupled in a stacked prototype arrangement (i.e., where access to the circuits is limited).

In another example embodiment of the present invention, a hardware configurator (i.e., a microcontroller) is disposed on a circuit module and programmed to monitor testing signals for routing on the circuit module using interrupt and initialization routines. The hardware configurator is programmable with the user interface and controls a plurality of switches on the circuit module in response to the monitored testing signals and/or inputs received from the user interface. In one implementation, one or more of JTAG-type TDI (test data in) and TDO (test data out) signals from various input pins on the circuit board are coupled to connectors on the hardware configurator and monitored using interrupts. Each of the signals is tied to a specific interrupt of the hardware configurator, with the hardware configurator being programmed with an interrupt routine for each of the signals. When the interrupt occurs, the programmed hardware configurator routes the proper path for the particular type of signal (i.e., as directed by the IEEE 1149.1 JTAG recommendation discussed above) using the switches. In various other implementations, other signals such as Test Clock (TCK) signals, Test Mode Select (TMS) and boundary-scan signals are also passed on and/or to and from the circuit module.

In another example embodiment of the present invention, a prototyping approach involves the use of a plurality of interchangeable circuits, each interchangeable circuit having a microcontroller and a switch that route test data and are controllable with a user interface coupled to the microcontroller. The microcontroller and switch may, for example, include one or more of the microcontroller/switch arrangements discussed herein. Each interchangeable circuit includes test data input (TDI) and test data output (TDO) nodes, with data being routed through test circuit paths in the interchangeable circuit under the control of the microcontroller. Also on each interchangeable circuit is a communications port for coupling to a user interface, either directly or through other interchangeable circuits, for inputting control signals for the microcontroller (e.g., for storing programming instructions and/or manually controlling a switch arrangement). Each of the interchangeable circuits is coupled to one or more programmable circuits, devices and/or functional blocks used for emulating a particular circuit design. For instance, circuit devices such as an FPGA (field-programmable gate array) device, an FPGA plug-in board, an expansion board and/or an external circuit communicatively coupled to the interchangeable circuit are used in various instances. These approaches have been found useful, for example, for circuit board development and as a support tool for silicon-on-chip platforms. The interchangeable circuits may be implemented, for example, in a manner such as discussed in U.S. application Ser. No. 10/016,731, entitled “Method and Arrangement for Rapid Silicon Prototyping” and filed on Dec. 11, 2001, which is a continuation of U.S. Pat. No. 6,347,395 (VLSI.206PA), entitled “Method and Arrangement for Rapid Silicon Prototyping” and filed on Dec. 18, 1998, both of which are fully incorporated herein by reference.

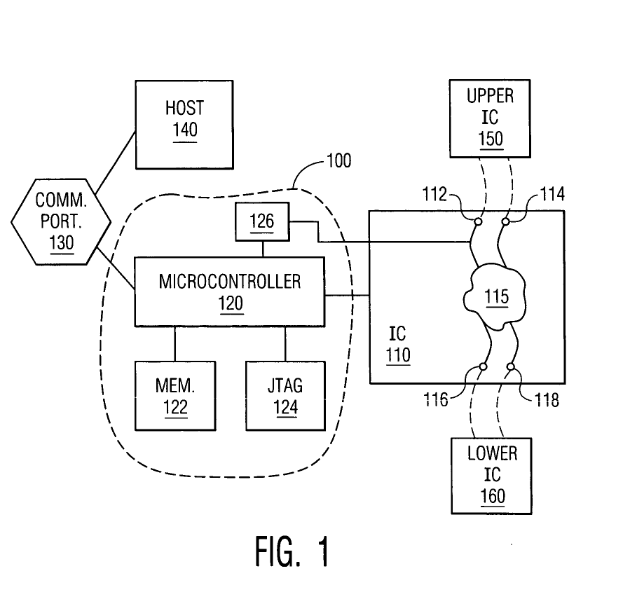

FIG. 1 is a configurator circuit 100 for monitoring and controlling an integrated circuit (IC) 110 (e.g., or other configurable circuit), according to another example embodiment of the present invention. The configurator system 100 includes a microcontroller 120 coupled to the IC 110. A memory 122, a JTAG controller 124 and a test signal sensing circuit 126 are also coupled to the microcontroller 120 and respectively used for storing JTAG program information, controlling JTAG signals for the IC 110 and sensing the presence of JTAG test signals.

In one implementation, the configurator circuit 100 further is adapted for interacting with a user interface 140, coupled to the configurator circuit through a communications port 130. In this instance, the configurator circuit responds to inputs received through the communications port 130, for direct control and/or for downloading program information to be stored in the memory 122. For example, user inputs from the user interface 140 are sent through the communications port 130 to the microcontroller 120 where they can be stored at the memory 122 and/or immediately used for execution, for example, using the JTAG controller 124 to control JTAG operations in the IC 110.

JTAG signal path switches 115 on the IC 10 route data within the IC and/or to and from circuits coupled to the IC. These JTAG signal path switches 115 are manually switchable using the user interface 140 and automatically switchable using programmed information stored at the memory 122. In one implementation, general-purpose input output (GPIO) controls, located in the microcontroller 120 and/or coupled to the microcontroller are used for controlling the JTAG signal path switches 115. For general information regarding ICs and JTAG-type approaches, and for specific information regarding approaches to automatic switching for JTAG routing that may implemented in connection with the present invention, reference may be made to U.S. Provisional Patent Application Serial No.______ (US030051P/NVLSI.379P1), filed on Mar. 4, 2003, entitled “Testing Circuit and Approach Therefore” and fully incorporated herein by reference.

In one implementation, the IC 110 is coupled to one or more other similar ICs, with the test signal sensing circuit 126 detecting the presence of test signals, and thereby the connectivity to similar ICs. For example, upper input and output pins 112 and 114, respectively, can be coupled to an upper IC 150 for communicating JTAG test signals. When test signals are detected at node 112 by the test signal sense circuit 126, the microcontroller 120 responds by setting JTAG signal path switches 115 to route test signals from the upper IC 150 to the IC 110 by way of node 112. The test signals are then passed through JTAG test paths on the IC 110 and routed back to the upper IC through output pin 114. In this example, the communications port 130 is optionally coupled to the user interface 140 by way of a communications port on the upper IC 150 (i.e., with the upper IC 150 being a “master” IC, routing JTAG signals to other ICs). Optionally, the communications port 130 is coupled directly to the user interface 140, with the communications port on the upper IC being coupled directly and/or though the communications port 130 to the user interface 140. The routing of the JTAG test signals is accomplished using the JTAG signal path switches 115 on the IC 110, as discussed above, using control inputs from the user interface 140 and/or stored programming at the memory 122. For instance, a user at the user interface 140 can issue a command that cuts off signals to and/or from the upper IC 150, or otherwise control the routing of JTAG signals on the IC 110 between the IC 110 and other circuits. In addition, the microcontroller 120 is also optionally adapted for controlling JTAG signal path switches on the upper IC 150, using the JTAG controller 124 and routing control signals through input and/or output pins 112 and 114.

In another example, a lower IC 160 is coupled to the IC 110 at lower output and input pins 116 and 118, respectively, using an approach similar to that discussed above in connection with the upper IC 150. The lower IC 160 is also coupled to the user interface 140, either by way of a communications port on the lower IC or through the communications port on the IC 110. In one instance, both the upper and lower ICs 150 and 160 are respectively coupled to the IC 110. Inputs received at upper input pin 112 are routed through JTAG signal paths on the IC 110 and out the lower output pin 116 to the lower IC 160 using the JTAG signal path switches 115. Outputs from the lower IC 160, responsive to the JTAG signals received from the output pin 116, are routed to the input pin 118 and, using the JTAG signal path switches 115, back to the upper IC 150 by way of output pin 114. Responses to the JTAG signals from one or all of the ICs 110, 150 and 160 can be routed to the user interface 140.

In one implementation, the microcontroller 120 monitors the IC 110 during both operational and non-operational modes thereof. Data regarding monitored circuits in the IC 110 is sent through the communications port 130 to the user interface 140, where users can monitor aspects of the IC 110. In addition to the monitoring of JTAG signals and responses as discussed above, a variety of characteristics of the IC 110 can be monitored using the microcontroller 120. For instance, prior to power-up of the IC 110, characteristics of the IC 110 are tested for diagnostics or other purposes. Proper connectivity between circuit modules (e.g., JTAG modules) and other ICs coupled to IC 110, as well as the operation of the IC 110 can thus be tested before use of the IC. In other instances, characteristics such as clock frequencies (e.g., using timers) and voltages of the IC 110 (e.g., using an analog-to-digital converter (ADC)) are monitored with the microcontroller 120. For example, when a clock frequency is different than design or when a voltage falls below a threshold, an error signal can be used to communicate these characteristics to a user. These characteristics can then be passed through the communications port 130 to a user at the user interface 140. Optionally, data regarding the monitored circuits is instead communicated using other means, such as an indicator light, audio signal or other recognizable signal.

Various ones of the elements shown in FIG. 1 are implemented using a variety of approaches, for example, depending upon the available equipment, type of signals being passed and desired functionality. For instance, the user interface 140 includes one or more of a variety of graphical and non-graphical user interfaces that facilitate two-way communication between the user interface and the microcontroller 120. A variety of user input devices, such as keyboards, pointing devices and touch screens may thus be implemented in connection with the user interface 140. Similarly, the communications link 130 is replaced with other suitable communications links, such as a USB link, wireless and/or wired links and others. Also, a variety of types of memory may be used in addition to or as the memory 122, such as FLASH and/or SRAM memory. Communications between these and other components in the configurator system 100 are also optionally effected using a bus controller in the IC 110, such as a 12C bus controller, to which the microcontroller 120, memory 122, JTAG controller 124 and communications link 130 can be coupled.

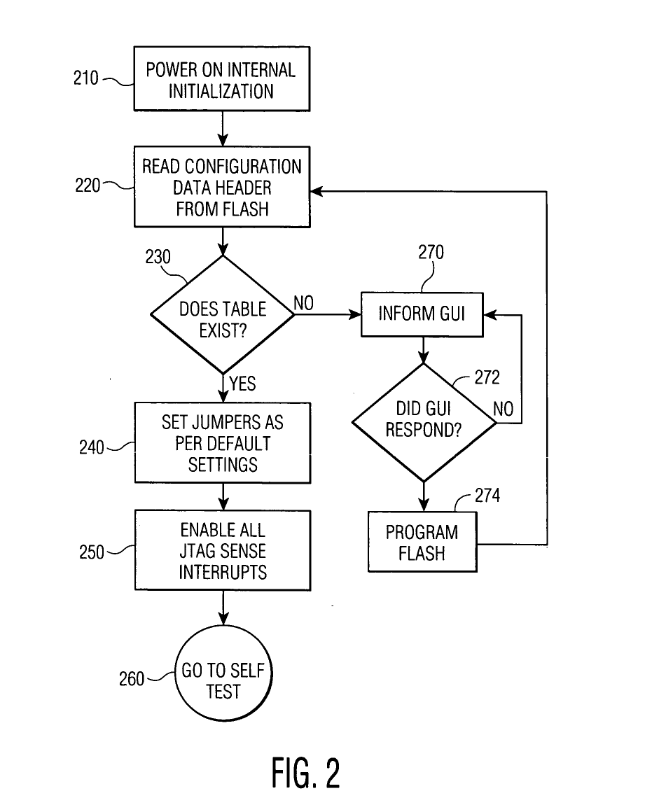

FIGS. 2-7 show several approaches that may be implemented in connection with circuits discussed herein, such as those discussed above in connection with FIG. 1 (i.e., the microcontroller 120 can be programmed using these approaches). Various ones of these approaches are separately applicable in connection with different example embodiments of the present invention. In addition, these approaches may be implemented together, with operation of a configurator circuit following the figures; the discussion of FIGS. 2-7 below follows this approach.

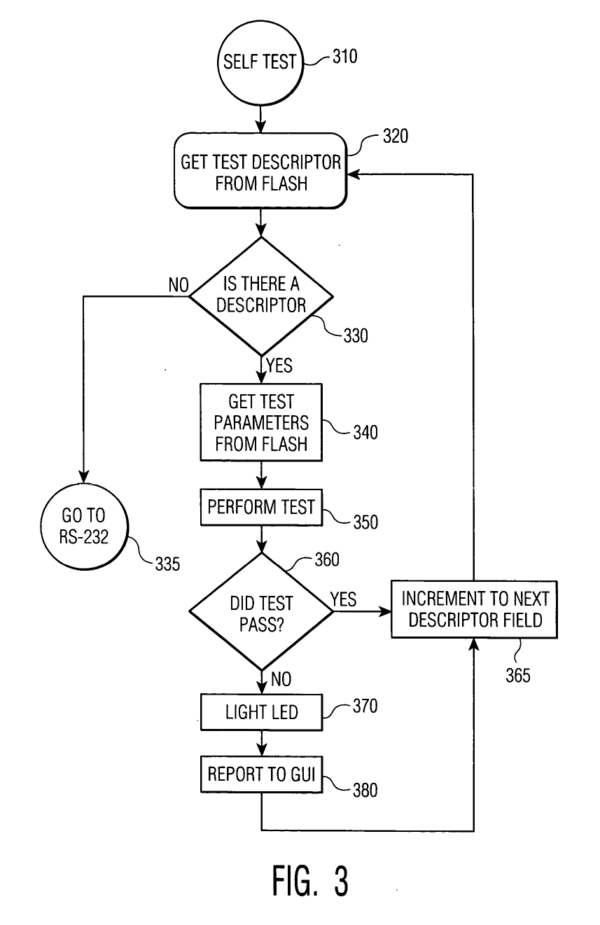

Referring to FIG. 2, a configurator circuit is powered for initialization in connection with another example embodiment of the present invention. At block 210, an internal initialization is carried out for a configurator circuit arrangement. A configuration data header is read from FLASH memory at block 220, and if a programming table (for use in controlling JTAG signals on the IC) does not exist at node 230, a graphic user interface (GUI) device is informed at block 270. If the GUI responds at node 272, the FLASH memory is programmed with the response at block 274. If the GUI does not respond at node 272, the GUI is re-informed at block 270, with the process at block 270 and node 272 being repeated (e.g., at a selected time interval or with a continuous display at the GUI) until a response is received. After the FLASH is programmed, the process continues again at block 220. Once a table is found to exist at node 230, jumpers (e.g., JTAG signal path switches) are set at block 240, all JTAG sense inputs for detecting JTAG signals are enabled at block 250, and a self-test (FIG. 3) is begun at node 260.

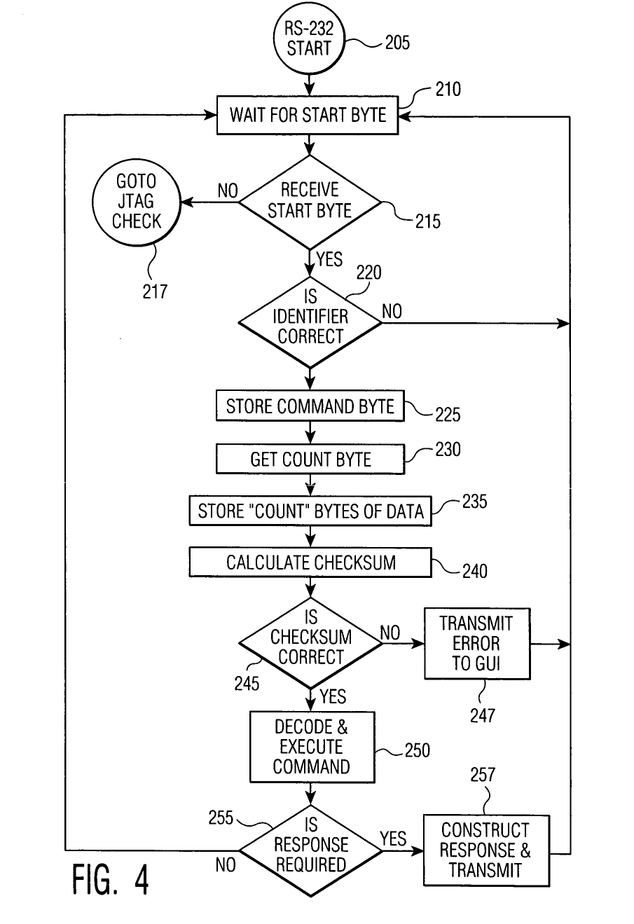

FIG. 3 shows a self-test approach, according to another example embodiment of the present invention. The self-test is initiated at node 310, with a test descriptor being obtained from FLASH memory at block 320. If a descriptor is not present at node 330, an RS-232 port is queried at node 335, as discussed further in connection with FIG. 4 to obtain a descriptor. Once a descriptor is available, test parameters are retrieved from FLASH memory at block 340, and a test is performed at block 350 (e.g., a connectivity or clock frequency test). If the test fails at node 360, an LED is lit at block 370 and the GUI is informed at block 380. If the test passes at node 360, or after the GUI has been informed at block 380, an increment is made to a next descriptor field at block 365 (e.g., for performing additional tests), and the process continues at block 320 until tests in the FLASH have been performed. Referring again to FIG. 1, this approach can be implemented for testing the IC 110 using information stored at the memory 122 (e.g., implemented as the FLASH memory discussed above).

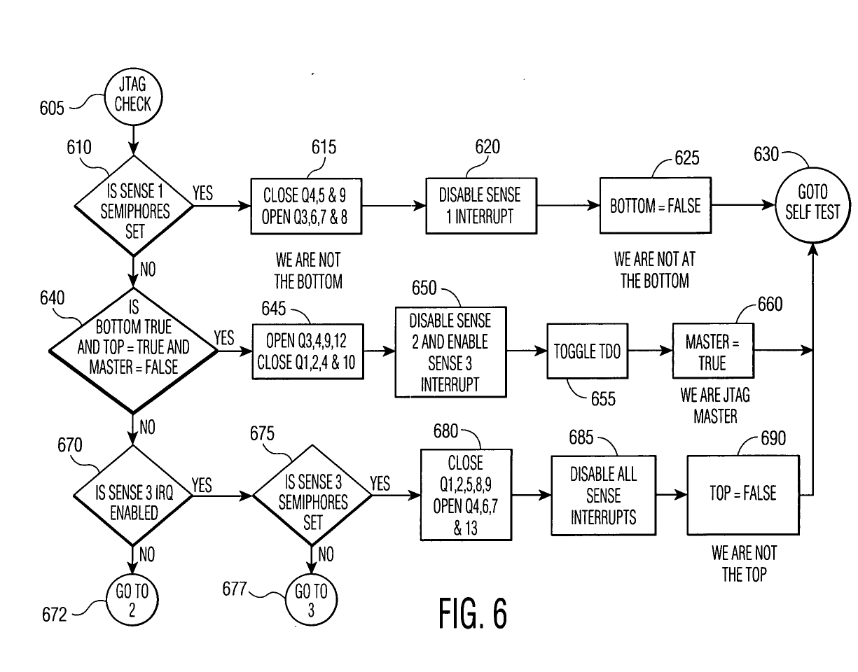

FIG. 4 shows an approach for communicating with an RS-232 port at a JTAG hardware configurator, according to another example embodiment of the present invention. At node 405, RS-232 communications are started, with the process beginning by waiting for a start byte at block 410. If a start byte is not received at node 415, a JTAG signal check is performed at node 417 (e.g., in connection with FIG. 6, discussed below). When a start byte is received at block 415, an identifier is checked at node 420, and if incorrect, the process resumes at block 410. If the identifier is correct at node 420, a command byte received through the RS-232 port is stored at block 425, a count byte is accessed at node 430 and used for storing bytes of data at node 435 having a length set by the count byte. A checksum is calculated at block 440 to detect that the proper bytes have been received, and if the checksum is incorrect at node 445, an error is transmitted to the GUI at block 447,and the process resumes at node 410. If the checksum is correct at node 445, the command (bytes of data) is decoded and executed at node 450. If a response is required at node 455, a response is constructed and transmitted at node 457. The process then returns to node 410. With this approach, control signals from a remote GUI can be implemented for controlling a hardware configurator arrangement, such as the arrangement 100 in FIG. 1.

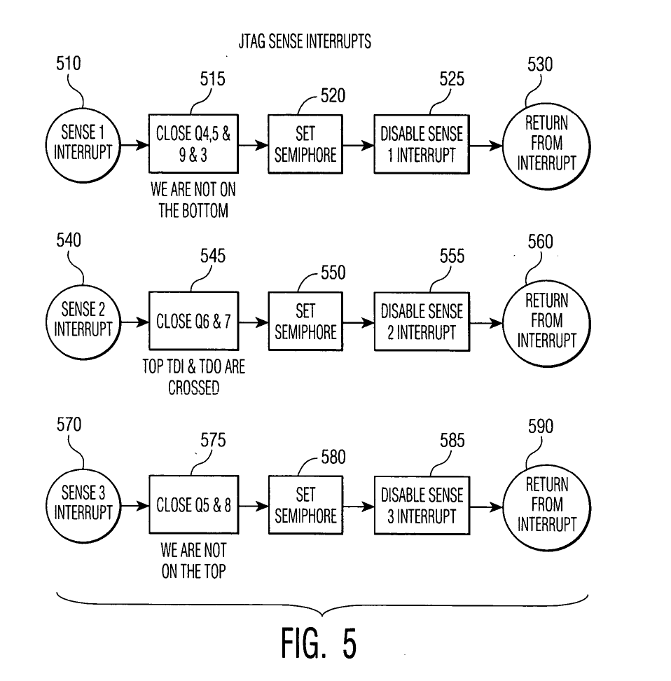

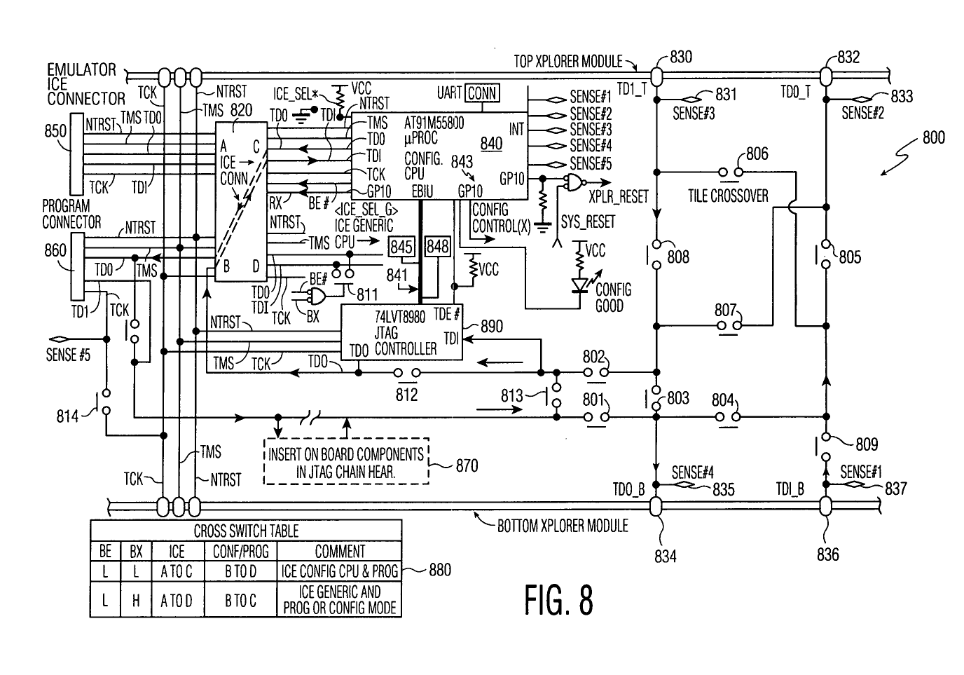

FIG. 5 is an approach for detecting the position of a JTAG-compatible circuit, relative to other JTAG-compatible circuits coupled thereto in a stacked arrangement, according to another example embodiment of the present invention. This approach may, for example, be implemented in connection with the stackable prototype circuit shown in FIG. 8 and discussed further below. By way of example, FIG. 5 is discussed in connection with the circuit shown in FIG. 8. At node 510, a first sense interrupt routine for test node 836 is begun, with switches 803, 804, 805 and 809 being closed at block 515 in response to no signal being detected at test node 836, using a first test signal sense circuit 837. At block 520, a first semiphore (e.g., a software flag or indicator light) is set, and a JTAG signal sense interrupt coupled to test node 832 is disabled at block 525 (i.e., test signal sense circuit 833 is disabled), with the first sense interrupt routine ending at node 530.

At node 540, a second sense interrupt routine for lest node 832 is begun, using a second test signal sense circuit 833, showing signals at test nodes 830 and 832 having been discovered as being crossed. At block 545, switches 806 and 807 are closed in response, a semiphore is set at block 550, a sense interrupt for test node 832 is disabled and the second sense interrupt routine is ended at node 560.

At node 570, a third sense interrupt routine is initiated, using a third test signal sense circuit 831, where no test signals are detected from an upper JTAG-compatible circuit. At block 575, switches 805 and 808 are closed, a semiphore is set at block 580, a sense interrupt for test node 830 is disabled at block 585 (i.e., the test signal sense circuit 831 is disabled) and the interrupt routine ends at node 590.

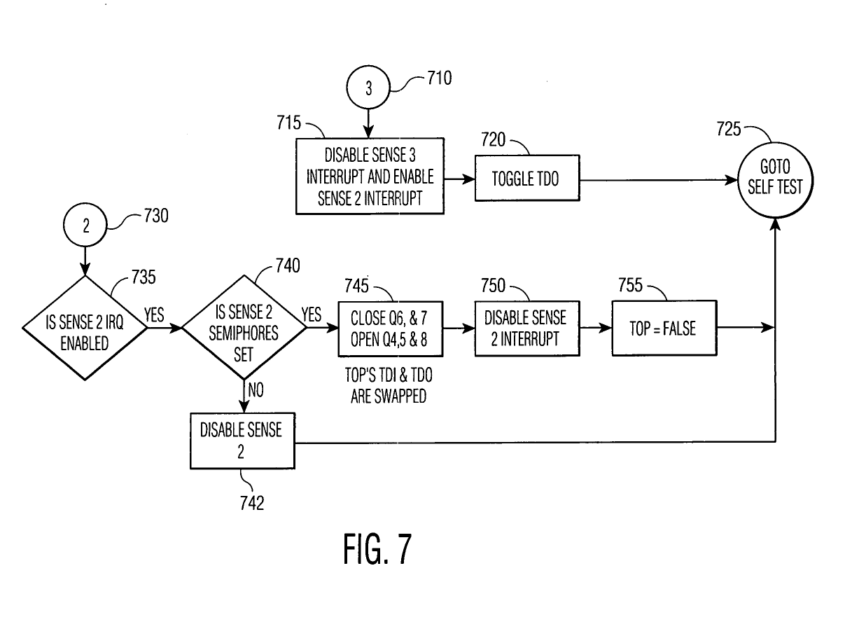

FIGS. 6 and 7 show an approach for performing a JTAG signal check, according to another example embodiment of the present invention. The JTAG signal check approach may, for example, be performed in connection with the approach discussed in connection with node 417 in FIG. 4. In addition, the approaches in FIGS. 6 and 7 may also be implemented in connection with the interrupt routines discussed in connection with FIG. 5; by way of example, the approaches shown in FIGS. 6 and 7 are discussed in the context of the interrupt routines shown in FIG. 5.

At node 605, the JTAG signal check is initiated and, if the first semiphore is set, switches 804, 805 and 809 are closed, and switches 803, 806, 807 and 808 are opened at block 615. The sense interrupt for test node 836 is disabled at block 620 (i.e., disabling test signal sense circuit 837), and an indicator of whether a JTAG-compatible circuit is coupled to test nodes 834 and 836 is set to FALSE (i.e., no JTAG-compatible circuit present) at block 625. A self-test is then initiated at node 630, for example, as discussed in connection with FIG. 3.

If the first semiphore is not set at node 610 the process proceeds to node 640, here shown detecting whether JTAG-compatible circuits are coupled above and below the circuit being tested, and whether the circuit being tested is a master circuit (i.e., controls JTAG signal passing on all three circuits). If the circuit being tested is not the master and is coupled to JTAG-compatible circuits above and below, the process proceeds to block 645. This determination is made at node 640 using, for example, indicators such as that set in block 625, after detecting the presence of additional JTAG-compatible circuits at test nodes 830 and 832, or at test nodes 834 and 836. At node 645, switches 803, 804, 809 and 812 are opened, and switches 801, 802, 804 and 810 are closed. A sense interrupt for test nodes 830 and 832 are disabled (i.e., test signal sense circuits 831 and 833 are disabled), test data out (TDO) signals are toggled at node 655 and an indicator that the circuit being tested is the master is set to TRUE at block 660. A self-test is then initiated at node 630.

If the three conditions set out at node 640 are not met, a determination is made at node 670 as to whether a sense interrupt for test node 830 is enabled. If the sense interrupt for test node 830 is not enabled, the process proceeds to scenario 2 at node 672, shown in FIG. 7 and discussed below. If the sense interrupt for test node 830 is enabled at node 670 and the semiphore for the sense interrupt for test node 830 is not set, the process proceeds to scenario 3 at node 677, shown in FIG. 7 and discussed below. If the sense interrupt for test node 830 is enabled at node 670 and the semiphore for the sense interrupt for test node 830 is set, the process proceeds to block 680, where switches 801,802, 805, 808 and 809 are closed, and switches 804, 806, 807 and 813 are opened. At block 685, all sense interrupts are disabled, an indicator that the circuit being tested is not the top JTAG-compatible circuit is set to false at block 690 and a self-test is initiated at node 630.

FIG. 7 shows implementations of scenarios 2 and 3 as discussed above in connection with FIG. 6. Scenario 2 is initiated at node 730. If the sense interrupt for test node 832 is enabled at node 735 but a semiphore therefor is not set at node 740, the sense interrupt for test node 832 is disabled at block 742. The process the proceeds to a self test at node 725 (e.g., in connection with FIG. 3). If the sense interrupt for test node 832 and the semiphore therefor is set, switches 806 and 807 are closed and switches 804, 805 and 808 are opened at block 745 (i.e., to swap signals at test nodes 830 and 832). The sense interrupt for test node 832 is disabled at block 750, an indicator that the circuit being tested is not the top JTAG-compatible circuit is set to false at block 755, and a self-test is initiated at node 725.

Scenario 3 is initiated at node 710, with the sense interrupt for test node 830 being disabled (i.e., test signal sense circuit 831 is disabled) and the sense interrupt for test node 832 being enabled at block 715. Test data out (TDO) signals are triggered at block 720, and a self test is initiated at node 725.

FIG. 8 is a configurator circuit 800 including a central processing unit (CPU) 840 (e.g., a microcontroller) coupled to test nodes 830, 832, 834 and 836, according to another example embodiment of the present invention. The CPU 840 is programmed with software for responding to an initialization routine and for running interrupt (alternatively, data-polling) routines for monitoring test data. The programming software is stored, for example, in a FLASH memory accessible by the CPU 840. For instance, a FLASH memory 845 coupled to an external bus interface unit (EBIU) 841 may store the programming software. The CPU 840 controls the EBIU 841 for passing signals thereon. In response to monitored test data, the software operates the CPU 840 to control a plurality of switches 801-814 for routing test signals on the circuit 800 and to/from additional circuits coupled, for example, to one of the test nodes 830, 832, 834 and/or 836. GPIO circuits 842 and 843 are implemented for effecting the control of the plurality of switches 801-814.

An RS232 communications link 848 is optionally coupled to the EBIU 841 and used for communicating between the CPU 840 and a user, for example, at a computer coupled to the RS232 communications link 848. Control signals, programming software and other signals are sent to the circuit 800 through the RS232 communications link 848, and monitored characteristics of the circuit 800 are also sent from the circuit 800 by way of the RS232 communications link.

Test nodes 830 and 832 are TDI and TDO nodes, respectively, that are adapted for coupling to another circuit (e.g., a similar circuit stacked over the circuit 800). Test nodes 834 and 836 are TDI and TDO nodes, respectively, that are adapted for coupling to another circuit (e.g., a similar circuit stacked below the circuit 800). Test signal sense circuits 831, 833, 835 and 837 are coupled respectively to test nodes 830, 832, 834 and 836, and also to the CPU 840 for sensing the presence of test signals at the test nodes. The connectivity of the configurator circuit 800 to other circuits is detected by the presence (or lack thereof) at signals at the test nodes. Test signals such as TCK, TMS, TDI and TDO are passed to one or more JTAG-compatible circuits 870 (e.g., CPUs or FPGAs). In addition, in the instance where one or more pairs of the test nodes 830, 832, 834 and 836 is coupled to another circuit, the test signals are passed to and from the other circuit.

The CPU 840 is coupled to a connector 820 by way of a first node C and to other circuitry and devices in the circuit 800. Node A at the connector 820 is coupled to an in-circuit emulator (ICE) connector 850, node B of the connector is coupled to both a program connector 860 and an on-circuit JTAG controller 890 and node D of the connector is optionally coupled to another CPU. The ICE connector 850 is adapted for coupling to an ICE, such as the “Majic” multi-processor advanced JTAG interface controller available from Embedded Performance, Inc. of Milpitas, Calif. Signals are applied to ICE connector 850 for emulation, such as in connection with the ARM 946ES RISC processor available from Arm, Inc. having a location in Redmond, Wash. The program connector 860 is adapted for coupling to a JTAG signal source, such as a tester or another stackable circuit, similar to the circuit 800, for supplying test signals to the circuit 800. The on-circuit JTAG controller 890 is also coupled to the CPU 840 by way of the EBIU 841 for communications therebetween.

The CPU 840 is adapted to be interrupted by test activity at the TDI and TDO nodes 830, 832, 834 and 836, with each node being tied to one or more interrupt input ports of the CPU. The particular node at which test data is detected informs CPU 840 for controlling the switches 801-814 for routing the data to a particular test circuit path, as indicated by the particular (interrupting) node. For example, as discussed below, a variety of circuit paths on the circuit 800 as well as between the circuit 800 and other circuits can be selected using the switches 801-814.

Using the CPU 840, the switches 801-814 are controlled for coupling test inputs from one or more of a plurality of sources to JTAG-compatible circuits 870 and for routing data to and from JTAG-compatible components. In one instance, JTAG test inputs are coupled to the circuit 800 from an external tester, such as an ICE coupled to ICE connector 850, a JTAG program device coupled to program connector 860 or from another circuit (i.e., with input/outputs coupled to the test nodes 830 and 832 or the test nodes 834 and 836). In another instance, JTAG testing is carried out on the circuit 800 using the on-circuit JTAG controller 890.

For example, when the CPU 840 detects a signal at the program connector 860, switch 810 is controlled (open) so that a TDI signal from the program connector 860 is sent to the JTAG-compatible circuits 870. In addition, switch 814 is closed to couple a TCK signal from the program connector 860 to the circuit 800. When no signal is detected at the program connector 860 (or when connection to the program connector is not desired), switch 810 is controlled (closed) to couple a test signal from node B of the connector 820 to the JTAG-compatible circuits 870. Switch 814 is also correspondingly opened such that a TCK signal from the program connector 860 is not coupled to the circuit 800.

In another example, when the CPU 840 detects a signal at the input nodes 830 and 832, a test input signal from node 830 is coupled to one or more of the JTAG-compatible circuits 870 with the closing of switches 808, 802 and 812. Switches 813 and 803 are set open, and an output from the JTAG-compatible circuits 870 is coupled for output from the circuit 800 (e.g., through test node 832, with switches 804 and 805 also being closed and with switch 809 being open).

In another example, the CPU controls the switches such that a signal is provided to the TDO node 834 and monitors TDI node 836. When a signal is detected at TDI node 836, the CPU 840 sets switches 804 and 803 open and switch 809 closed for routing output test data from the circuit 800 to a circuit coupled to test nodes 834 and 836.

In another example embodiment, the on-circuit JTAG controller 890 is implemented for a stand-alone JTAG test implementation. In this example, switches 810 and 813 are closed and at least switches 812, 814, 801 and 802 are opened. With this approach, signals from the on-circuit JTAG controller 890 are routed to the JTAG-compatible circuits 870, with an output therefrom being routed back to the JTAG controller 890.

In one particular implementation, and referring again to FIG. 8, two circuit boards (upper and lower) containing IEEE 1149.1 JTAG compatible devices, similar to the circuit 800 shown in FIG. 8, are stacked together. Fur instance, such an arrangement may be implemented in a manner similar to that discussed in connection with upper IC 150 and lower IC 160 in FIG. 1. The following discussion is directed to the upper and lower boards having elements similar to those shown in FIG. 8, with corresponding discussion of the elements in FIG. 8 for both of the upper and lower boards having an upper or lower indicator in brackets. For instance, each of the upper and lower boards include node 830, with node 830 on the upper board being designated as “node 830 (upper board)” and node 830 at the lower board being designated as “node 830 (lower board).”

The upper one of the circuit boards is coupled to a JTAG programmer plugged into a program connector 860 (upper board). A TDI signal is sent out to the lower board at node 834 (upper board) and received at the lower board through a node 830 (lower board). The upper circuit board monitors a TDI node 836 (upper board) and detects a signal returning from the lower board through a TDO node 832 (lower board). In response to the detected signal, the CPU recognizes that the lower board is coupled to the upper board at nodes 834 (upper board) and 836 (upper board) and accordingly sets the switches (i.e. switch 809 is set closed and switch 304 is set open).

The various embodiments described above and shown in the figures are provided by way of illustration only and should not be construed to limit the invention. Based on the above discussion and illustrations, those skilled in the art will readily recognize that various modifications and changes may be made to the present invention without strictly following the exemplary embodiments and applications illustrated and described herein. For example, as can be seen by the variety of switches 801-814 in FIG. 8, a plurality of combinations of open and closed switches can be used for routing data on the circuit 800 and to other circuits coupled to the circuit 800. Furthermore, one or more of the example embodiments discussed herein may be implemented in connection with the subject matter discussed in U.S. Provisional Patent Application Serial No.______ (US030078), entitled “Configurator Arrangement and Approach Therefor” and in U.S. Provisional Patent Application Serial No.______(US030079), entitled “Graphical User Interface and Approach Therefor,” both of which are filed concurrently herewith and fully incorporated herein by reference. These approaches are implemented in connection with various example embodiments of the present invention. Such modifications and changes do not depart from the true spirit and scope of the present invention that is set forth in the following claims.

What is claimed is:

1. For use in controlling routing circuitry having configurable test signal routing paths with controllable switches (805, 808) therein for coupling test signals between dedicated test-signal circuitry (830) and a target circuit device (870), a circuit configurator arrangement comprising:
a test-signal sense circuit (831) adapted to detect test signals carried by at least one of the test signal routing paths;
a switch-control interface circuit (842) adapted to control the controllable switches; and
a control logic circuit (840) adapted to send control signals to the switch-control interface circuit, in response to the detected test signals carried by said at least one of the test signal routing paths, and therein adaptively control routing of test signals in the configurable test signal routing paths.

2. The circuit configurator arrangement of claim 1, further comprising a communications link adapted to communicatively couple the control logic circuit to an external user-controlled device for passing reconfiguration-control signals to the control logic circuit, the control logic circuit being adapted to respond to the reconfiguration-control signals by sending control signals to the switch-control interface circuit for adaptively controlling the routing of the test signals in the configurable test signal routing paths.

3. The circuit configurator arrangement of claim 2, further comprising a memory adapted to store the reconfiguration-control signals for access by the control logic circuit, the stored reconfiguration-control signals, when executed, causing the control logic to send control signals to the switch-control interface circuit for adaptively controlling the routing of the test signals in the configurable test signal routing paths.

4. The circuit configurator arrangement of claim 2, wherein the communications link is further adapted for reporting characteristics of the configured test signal routing paths to the external user-controlled device.

5. The circuit configurator arrangement of claim 1, further comprising a memory adapted to store said control signals for access by the control logic circuit, the stored control signals, when executed, causing the control logic to send signals to the switch-control interface circuit for adaptively controlling the routing of the test signals in the configurable test signal routing paths.

6. The circuit configurator arrangement of claim 1, wherein the test-signal sense circuit is adapted to detect test signals passing between the configurable test signal routing paths and an external circuit and wherein the control logic circuit is adapted to adaptively control routing of test signal between the configurable test signal routing paths and the external circuit, in response to the detected test signals.

7. The circuit configurator arrangement of claim 1, wherein the dedicated test-signal circuitry includes a test-data input port adapted to receive test data, a test-data output port adapted to pass test data from the dedicated test-signal circuitry and a test-clock port.

8. The circuit configurator arrangement of claim 1, wherein the control logic circuit is programmed to control and monitor a plurality of operational characteristics of the configurable test signal routing paths.

9. The circuit configurator arrangement of claim 1, wherein the configurable test signal routing paths include a plurality of JTAG signal path switches adapted to route JTAG signals on the routing circuitry and between the routing circuitry and an external circuit, and wherein the control logic circuit is programmed to send the control signals to configure the plurality of JTAG signal path switches.

10. The circuit configurator arrangement of claim 9, wherein the control logic circuit is programmed to switch the plurality of JTAG signal path switches in response to reconfiguration-control signals received from an external user-controlled device.

11. The circuit configurator arrangement of claim 1, wherein the control logic circuit is adapted to monitor operational characteristics of the routing circuitry prior to power-up of the routing circuitry.

12. The circuit configurator arrangement of claim 1, wherein the control logic circuit is adapted to send control signals to the switch-control interface circuit and therein set the controllable switches, prior to power-up of the routing circuitry.

13. The circuit configurator arrangement of claim 1, wherein the control logic circuit is further adapted to control a JTAG controller for generating JTAG test signals and adaptively control the routing of the generated JTAG test signals in the configurable test signal routing paths.

14. For use with a configured circuit (110) having a plurality of controllable switches (115) communicatively coupled between at least two JTAG test nodes (112, 114) on JTAG signal paths and target circuit devices along the JTAG signal paths, a circuit configurator arrangement (100) comprising:
a communications port (130) adapted to accept control inputs from a user interface (140) via a communications link and to provide output data to the user via the communications link;
a test-signal sense circuit (126) adapted to detect JTAG test signals carried by at least one of the test signal routing paths;
a memory (122) having computer-executable code; and
a programmable microcontroller (120) communicatively coupled to the configured circuit, the communications port and the test signal sense circuit, wherein the computer-executable code, when executed, causes the microcontroller to control the controllable switches for coupling JTAG test signals to the target circuit devices in response to test signals sensed by the test-signal sense circuit, and to monitor operational characteristics of the configured circuit and output data to the user interface 140 in response to the monitored operational characteristics.

15. The circuit configurator arrangement of claim 14, wherein the microcontroller is programmed to cause the test-signal sense circuit to monitor the JTAG test nodes using an interrupt routine for automatically detecting test signals at the JTAG test nodes.

16. The circuit configurator arrangement of claim 14, wherein the microcontroller is programmed to control the controllable switches for routing JTAG test data between the configured circuit and an external configured circuit, via the JTAG test nodes.

17. The circuit configurator arrangement of claim 14, wherein the microcontroller is adapted to control the controllable switches in response to control inputs received from the user interface via the communications port.

18. The circuit configurator arrangement of claim 14, wherein the circuit configurator arrangement is adapted to receive computer-executable code from the user interface via the communications port and to store the computer-executable code in the memory, the received and stored computer-executable code, when executed, causing the microcontroller to control the controllable switches.

19. The circuit configurator arrangement of claim 14, wherein the microcontroller is programmed to perform diagnostic testing on the configured circuit when the configured circuit is not powered and to report the results of the diagnostic testing via the communications port.

20. The circuit configurator arrangement of claim 19, wherein the microcontroller is programmed to report an error signal in response to the diagnostic testing indicating an error in the routing circuitry.

21. The circuit configurator arrangement of claim 19, wherein the microcontroller is adapted to perform diagnostic testing on timing circuits coupled to the routing circuitry by detecting clock frequency thereof and, in response to detecting an improper clock frequency, to report an error signal indicating a timing error.

22. The circuit configurator arrangement of claim 14, further comprising an analog-to-digital converter (ADC) coupled to the configured circuit and adapted for converting detected analog signals thereon to digital signals, the microcontroller being further adapted for reporting characteristics of the configured circuit in response to the digital signals.

23. For use in a prototype arrangement of inter-connectable circuit boards, each of the inter-connectable circuit boards having JTAG test signal routing switches (115), at least two JTAG circuit paths and JTAG input/output (I/O) test nodes (112, 114, 116, 118) for passing JTAG test signals to and from other inter-connectable circuit boards (150, 160), a configurator circuit comprising:
a memory (122) adapted to store data including computer-executable code;
a microcontroller (120) on a first one of the inter-connectable circuit boards and communicatively coupled to the memory, the computer-executable code, when executed, causing the microcontroller to:
monitor the JTAG I/O test nodes to detect connectivity to another inter-connectable circuit; and
automatically configure the JTAG test signal routing switches in response to the JTAG I/O test node monitoring for routing JTAG test signals along a JTAG circuit path on at least the first one of the inter-connectable circuit boards; and
a communications link (130) adapted to communicate control inputs from a user interface device (140) to the microcontroller and to communicate outputs from the microcontroller to the user interface, the microcontroller being operable in response to the control inputs.

24. The configurator circuit of claim 23, wherein the computer-executable code, when executed, causes the microcontroller to monitor the JTAG I/O test nodes and, in response to detecting connectivity to another inter-connectable circuit via the monitoring, to set the controllable switches for routing JTAG test signals between the inter-connectable circuits.

25. The configurator circuit of claim 23, wherein the computer-executable code, when executed, causes the microcontroller to monitor the JTAG I/O test nodes and, in response to detecting that another inter-connectable circuit is not connected to a particular JTAG test node via the monitoring, to set the controllable switches for routing a-way from the particular JTAG test node.

26. The configurator circuit of claim 23, wherein the microcontroller is adapted to set the JTAG test signal routing switches in response to control inputs received from the user interface.

27. The configurator circuit of claim 23, wherein the computer-executable code, when executed, causes the microcontroller to perform an interrupt routine for monitoring the JTAG I/O test nodes.

28. The configurator circuit of claim 23, wherein the computer-executable code, when executed, causes the microcontroller to perform a data-polling routine for monitoring the JTAG I/O test nodes.

29. For use in controlling routing circuitry having configurable test signal routing paths with controllable switches (805, 808) therein for coupling test signals between dedicated test-signal circuitry (830) and a target circuit device (870), a circuit configurator arrangement comprising:
test-signal sensing means (831) for detecting test signals carried by at least one of the test signal routing paths;
switch-control interface means (842) for controlling the controllable switches; and
control logic means (840) for sending control signals to the switch-control interface circuit, in response to the detected test signals carried by said at least one of the test signal routing paths, and therein adaptively control routing of test signals in the configurable test signal routing paths.
